(19) United States
(12) Patent Application Publication
(10) Pub. No.: US 2025/0275228 A1
(43) Pub. Date: Aug. 28, 2025

(54) LIGHT EMITTING DEVICE

(71) Applicant: FUJIFILM Business Innovation Corp., Tokyo (JP)

(72) Inventor: Daisuke IGUCHI, Kanagawa (JP)

(73) Assignee: FUJIFILM Business Innovation Corp., Tokyo (JP)

(21) Appl. No.: 18/810,768

(22) Filed: Aug. 21, 2024

(30) Foreign Application Priority Data
Feb. 27, 2024 (JP) 2024-027742

(51) Int. Cl. H01L 27/06; H01L 27/15; H01L 33/00; H01L 33/10

(52) U.S. Cl. CPC H10D 84/206; H10H 20/81; H10H 29/10; H10H 20/814

(57) ABSTRACT

A light emitting device includes: a light emitting unit that includes plural light emitting elements; a transfer unit that transfers a signal for setting a light emitting element to turn into an on state among the plural light emitting elements; and a low-pass filter provided between a reference potential terminal of the transfer unit and an external reference potential.

### CROSS-REFERENCE TO RELATED APPLICATIONS

This application is based on and claims priority under 35 USC 119 from Japanese Patent Application No. 2024-027742 filed Feb. 27, 2024.

### BACKGROUND

### (i) Technical Field

The present disclosure relates to a light emitting device.

### (ii) Related Art

JP2023-140068A discloses that “the control unit 50 sets a control potential VC to a ground potential GND (0 V) in a shift period (at the time of selection) in which the shift unit 12 performs a shift operation, and sets the control potential VC to a potential (here, a floating potential (Hi-Z)) different from the potential in the period (at the time of selection) at the time of light emission”.

### SUMMARY

In a self-scanning light emitting device including a transfer unit, it is known that, for example, it is desirable to connect a reference potential terminal of the transfer unit to a reference potential in order to discharge charges from the transfer unit, but, in this case, the waveform of a current flowing in a light emitting element deteriorates due to the capacitance of the transfer unit. In the related art, a technique of suppressing the formation of capacitance in the transfer unit by bringing the reference potential terminal of the transfer unit into a floating state except for the time of a transfer operation to reduce waveform deterioration has been studied (for example, see JP2023-140068A). However, in the technique in the related art, it is necessary to provide a switch mechanism on a path to switch a connection state of the reference potential terminal in order to bring the reference potential terminal into the floating state.

Aspects of non-limiting embodiments of the present disclosure relate to a light emitting device capable of reducing waveform deterioration due to the capacitance of a transfer unit without switching a connection state of the reference potential terminal, as compared with a case where a reference potential terminal of the transfer unit is directly connected to a reference potential.

Aspects of certain non-limiting embodiments of the present disclosure overcome the above disadvantages and/or other disadvantages not described above. However, aspects of the non-limiting embodiments are not required to overcome the disadvantages described above, and aspects of the non-limiting embodiments of the present disclosure may not overcome any of the disadvantages described above.

According to an aspect of the present disclosure, there is provided a light emitting device including: a light emitting unit that includes a plurality of light emitting elements; a transfer unit that transfers a signal for setting a light emitting element to turn into an on state among the plurality of light emitting elements; and a low-pass filter provided between a reference potential terminal of the transfer unit and an external reference potential.

### BRIEF DESCRIPTION OF THE DRAWINGS

Exemplary embodiment(s) of the present invention will be described in detail based on the following figures, wherein:

FIG. 1 is a diagram showing an example of a cross-sectional view of a light emitting device 100′ in the related art;

FIG. 2 is a diagram showing an example of an equivalent circuit of the light emitting device 100′ in the related art;

FIG. 3 is a diagram showing a result of simulating a difference in light-emitting pulse waveform depending on the presence or absence of a transfer unit 130;

FIG. 4 is a diagram showing an example of terminal processing in a light emitting device 100 according to the present exemplary embodiment;

FIG. 5 is a diagram showing an example of component arrangement of the terminal processing in the light emitting device 100 according to the present exemplary embodiment;

FIG. 6 is a diagram showing an example of filter characteristics of a low-pass filter 220;

FIG. 7 is a diagram showing an example of a circuit used in a first simulation according to a first comparative example;

FIG. 8 is a diagram showing an example of a circuit used in the first simulation according to a second comparative example;

FIG. 9 is a diagram showing an example of a circuit used in the first simulation according to the present exemplary embodiment;

FIG. 10 is a diagram showing a result of the first simulation;

FIG. 11 is a diagram showing an example of a circuit used in a second simulation according to a third comparative example;

FIG. 12 is a diagram showing an example of a circuit used in the second simulation according to a fourth comparative example;

FIG. 13 is a diagram showing an example of a circuit used in the second simulation according to a fifth comparative example;

FIG. 14 is a diagram showing an example of a circuit used in the second simulation according to the present exemplary embodiment; and

FIG. 15 is a diagram showing a result of the second simulation.

### DETAILED DESCRIPTION

Hereinafter, an example of an exemplary embodiment of the present disclosure will be described with reference to the drawings. Identical reference numerals are assigned to identical or equivalent components and parts in each drawing. In addition, the dimensional ratios in the drawings are exaggerated for convenience of description and may differ from the actual ratios.

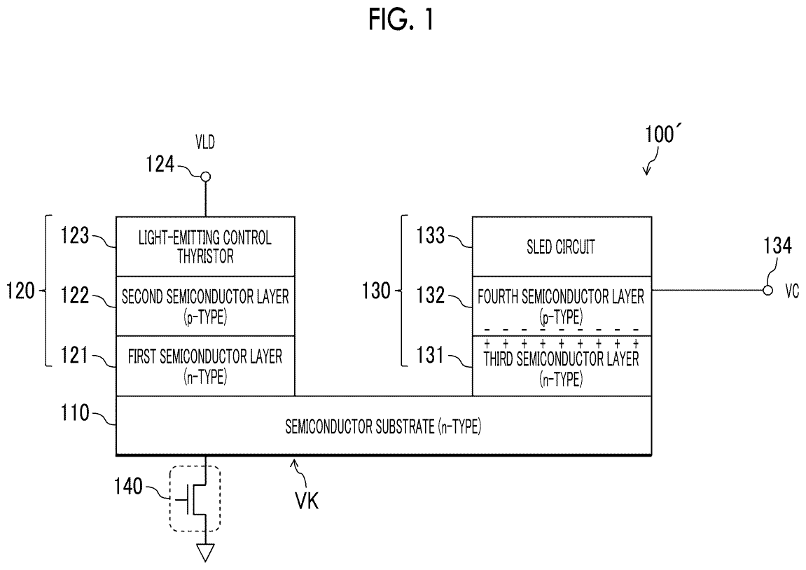

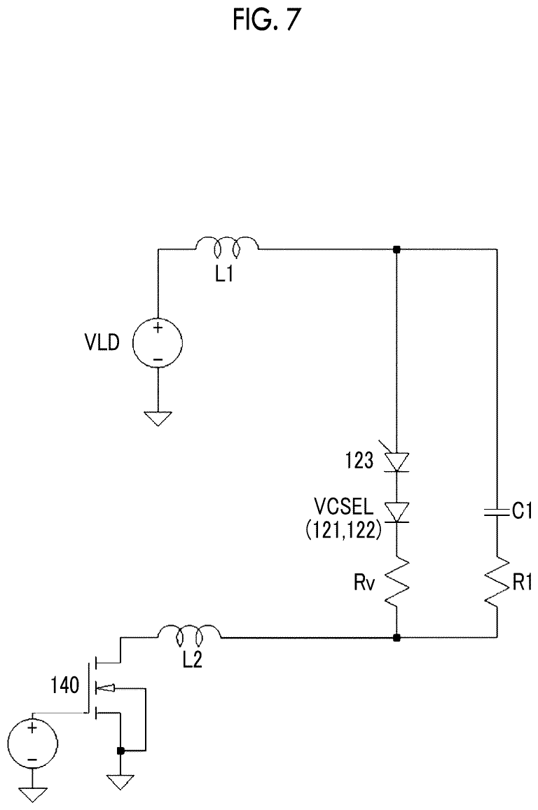

FIG. 1 is a diagram showing an example of a cross-sectional view of a light emitting device 100′ in the related art. The drawing corresponds to FIG. 7A in JP2023-140068A. The drawing shows a cross-sectional view focusing only on one vertical cavity surface emitting laser (referred to as a VCSEL below) in a case where the light emitting device 100′ includes a plurality of VCSELs as light emitting elements.

In the drawing, for convenience of description, description of an active layer, a tunnel junction layer, and the like will be omitted. The light emitting device 100′ includes a semiconductor substrate 110, a light emitting unit 120, a transfer unit 130, and a driver 140.

The semiconductor substrate 110 is an n-type semiconductor substrate. The semiconductor substrate 110 may be, for example, an n-type GaAs substrate. The light emitting unit 120 and the transfer unit 130 may be provided on the common semiconductor substrate 110. A potential on the back surface of the semiconductor substrate 110 is set as a substrate potential VK.

The light emitting unit 120 includes a plurality of light emitting elements. The light emitting unit 120 includes a first semiconductor layer 121, a second semiconductor layer 122, and a light-emitting control thyristor 123.

The first semiconductor layer 121 is an n-type semiconductor layer formed on the semiconductor substrate 110. The first semiconductor layer 121 may be, for example, a distributed Bragg reflector (DBR) in which AlGaAs having different Al compositions are alternately stacked. The second semiconductor layer 122 is a p-type semiconductor layer formed on the first semiconductor layer 121. The second semiconductor layer 122 may be a DBR, similar to the first semiconductor layer 121. As described above, the light emitting unit 120 may have a resonator structure in which the first semiconductor layer 121 functioning as an n-type lower reflective mirror, and the second semiconductor layer 122 functioning as a p-type upper reflective mirror are stacked in this order on an n-type semiconductor substrate. As a result, the VCSEL as the light emitting element is configured.

The light-emitting control thyristor 123 is a thyristor formed on the second semiconductor layer 122. In the light-emitting control thyristor 123, an anode may be connected to a light emitting potential terminal 124 to which a light emitting potential VLD is supplied, and a cathode may be connected to an anode of the VCSEL. That is, the light-emitting control thyristor 123 may be connected in series to the VCSEL.

The transfer unit 130 transfers a signal for setting the light emitting element to turn into an on state among the plurality of light emitting elements. The transfer unit 130 corresponds to the “shift unit 12” in JP2023-140068A. The transfer unit 130 includes a third semiconductor layer 131, a fourth semiconductor layer 132, and an SLED circuit 133.

The third semiconductor layer 131 is an n-type semiconductor layer formed on the semiconductor substrate 110, similar to the first semiconductor layer 121. The fourth semiconductor layer 132 is a p-type semiconductor layer formed on the third semiconductor layer 131, similar to the second semiconductor layer 122. As described above, the transfer unit 130 may include a pn junction that is a structural body equivalent to the light emitting element.

The SLED circuit is a self-scanning light emitting element array that realizes self-scanning of the light emitting element. An SLED is an abbreviation for Self-scanning Light Emitting Device. The SLED circuit may include a shift thyristor and a coupling transistor.

The structures of the light emitting unit 120 and the transfer unit 130 may be the similar to the structures in JP2023-140068A, and thus, the detailed description thereof will be omitted. The description of JP2023-140068A may be incorporated herein by reference.

Here, a capacitive portion is formed between the fourth semiconductor layer 132, which is a p-type, and the semiconductor substrate 110, which is an n-type. More specifically, it is necessary to connect the fourth semiconductor layer 132 to the reference potential (for example, GND) in order to discharge charges from the SLED circuit 133, but a reverse bias is applied to the pn junction of the transfer unit 130 at the time of light emission of the VCSEL because the substrate potential VK is about 1 V. Therefore, the pn junction acts as the capacitive portion. In this case, since the transfer unit 130 occupies about half of the area of a chip, a relatively large capacitance is formed.

A terminal 134 that controls the potential of the capacitive portion to a control potential VC is connected to the fourth semiconductor layer 132. Since the terminal 134 only needs to be connected to an external reference potential, the terminal 134 will be referred to as a reference potential terminal 134 below.

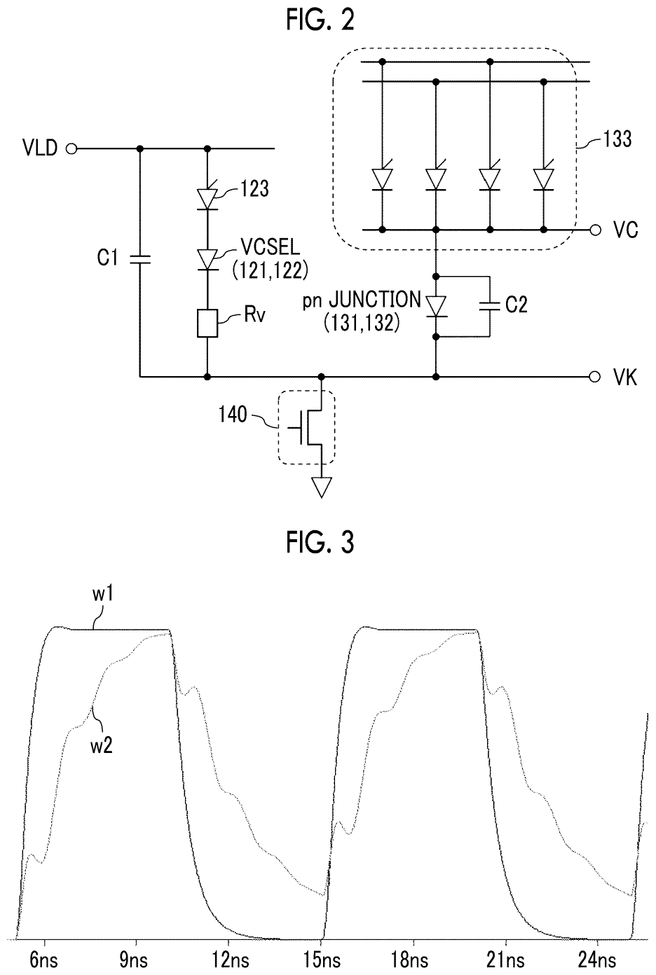

FIG. 2 is a diagram showing an example of an equivalent circuit of the light emitting device 100′ in the related art. The drawing corresponds to FIG. 7B in JP2023-140068A. The light emitting unit 120 is represented by a parallel connection of a series connection of a light-emitting control thyristor 123, a VCSEL (constituted by the first semiconductor layer 121 and the second semiconductor layer 122), and an internal resistance Rv with a capacitance C1.

The light emitting unit 120 is configured in a manner that a plurality of VCSELs and light-emitting control thyristors 123 which are connected in series are connected in parallel. Thus, the light-emitting control thyristors 123 and the VCSELs that are connected in series excluding the series connection that includes the VCSEL to be caused to emit light serve as the capacitance C1 connected in parallel to the series connection including the VCSEL to be caused to emit light.

The transfer unit 130 is represented by a parallel connection of a pn junction (indicated by a symbol of a diode in the drawing) configured with a third semiconductor layer 131 and a fourth semiconductor layer 132 and a capacitance C2 due to the pn junction, and a series connection of the parallel connection and an SLED circuit 133. For simplification, only the shift thyristor is shown in the SLED circuit 133. Here, a light-emitting pulse waveform deteriorates due to the capacitance C2 formed in the transfer unit 130.

FIG. 3 is a diagram showing a result of simulating a difference in light-emitting pulse waveform depending on the presence or absence of the transfer unit 130. A waveform w1 indicates a light-emitting pulse waveform in a case where the transfer unit 130 is not provided. A waveform w2 shows the light-emitting pulse waveform in a case where the transfer unit 130 is provided, and the reference potential terminal 134 is directly connected to the reference potential.

As shown in the drawing, it can be seen that, since the capacitance C2 due to the pn junction is added, not only waveform dullness occurs in the rising edge and the falling edge of a pulse waveform, but also waveform deterioration such as shoulders occurs due to resonance including a parasitic inductance of mounting.

Here, a capacitance formed between the fourth semiconductor layer 132, which is a p-type, and the semiconductor substrate 110, which is an n-type, does not have an influence on the waveform as long as the fourth semiconductor layer 132 is isolated from the reference potential. Thus, it is possible to suppress the formation of a capacitance in the transfer unit 130 by causing the fourth semiconductor layer 132 to float except at the time of a transfer operation. In the technique in the related art shown in JP2023-140068A, waveform deterioration caused by the capacitance formed in the transfer unit 130 is reduced in this manner.

However, the reference potential terminal 134 connected to the fourth semiconductor layer 132 is formed as a pad on a surface layer of a VCSEL element and is connected from the pad to an external reference potential, such as a package or a mounting substrate, by wire bonding. Thus, a connection from the reference potential terminal 134 to the reference potential is made outside the VCSEL element.

Here, in order to cause the fourth semiconductor layer 132 to float, it is necessary to provide a switch mechanism on such a connection path so that the connection to the reference potential can be turned off. Therefore, such a switch mechanism is required to be provided in an element that controls the VCSEL, in a VCSEL driver, or separately on the mounting substrate. In addition, in a case where the switch mechanism is separately provided, a signal for performing switching is required to be supplied to the switch mechanism.

Therefore, in the present disclosure, the waveform deterioration due to the capacitance of the transfer unit 130 is reduced by devising the terminal processing without switching the connection state of the reference potential terminal 134, as compared with a case where the reference potential terminal 134 is directly connected to the reference potential.

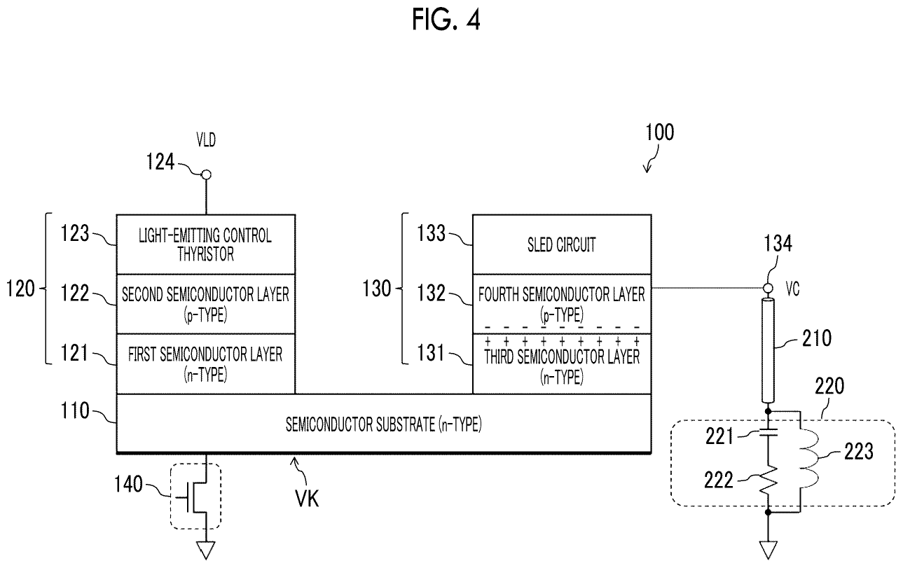

FIG. 4 is a diagram showing an example of terminal processing in a light emitting device 100 according to the present exemplary embodiment. In the drawing, the identical or equivalent components and parts as or to FIG. 1 are denoted by the same reference numerals, and the description thereof will be omitted except for the following differences.

In the present exemplary embodiment, the light emitting device 100 includes a low-pass filter 220 provided between the reference potential terminal 134 of the transfer unit 130 and an external reference potential.

In addition, in the present exemplary embodiment, the light emitting device 100 may further include a transmission line 210 provided between the reference potential terminal 134 and the low-pass filter 220. As described above, the transmission line 210 may be a bonding wire that is wire-bonded from the pad formed on the surface layer of the VCSEL element to the external reference potential of the VCSEL element. The length of the transmission line 210 may be equal to or more than, for example, 10 mm.

Here, the low-pass filter 220 may include a snubber circuit in which a capacitor 221 and a resistor 222 are connected in series. In general, the snubber circuit is a protective circuit provided to prevent an erroneous operation caused by a rapid increase in voltage during the opening and closing of a switch in an electronic circuit.

In this case, the low-pass filter 220 may satisfy a predetermined impedance matching condition between the low-pass filter 220 and the transmission line 210. Here, it is assumed that the bonding wire is 3 cm and an impedance of the transmission line 210 is about 45Ω, and the resistance value of the resistor 222 is about 46 Ω that is equivalent to an impedance of the transmission line 210 (47Ω in a case using a standard number of nominal resistance values displayed in three digits).

The capacitance of the capacitor 221 may be set based on the cut-off frequency determined by the time constant with the resistance value of the resistor 222. Here, the capacitance of the capacitor 221 is set to 0.1 μF.

In addition, the low-pass filter 220 may further include an inductor 223 connected in parallel with the snubber circuit. The inductance of the inductor 223 may be set based on the cut-off frequency. Here, the inductance of the inductor 223 is set to 1 μH.

As described above, the low-pass filter 220 may be configured by a parallel circuit of the snubber circuit in which the capacitor 221 and the resistor 222 are connected in series, and the inductor 223.

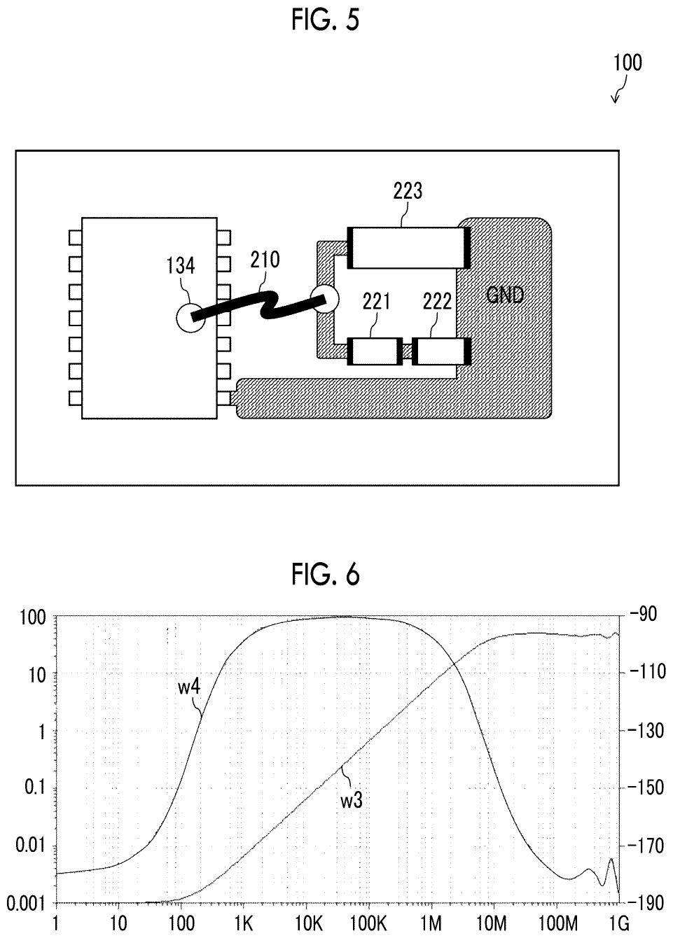

FIG. 5 is a diagram showing an example of component arrangement of the terminal processing in the light emitting device 100 according to the present exemplary embodiment. FIG. 5 is a diagram of the component arrangement in a case where the reference potential terminal 134 of the VCSEL element mounted on the mounting substrate is connected to the external reference potential (in the drawing, GND of the mounting substrate) through the transmission line 210 and the low-pass filter 220, as viewed from the top surface.

In a case where the reference potential terminal 134 is connected to the external reference potential, the transmission line 210, the capacitor 221, the resistor 222, and the inductor 223 may be arranged as shown in the drawing, for example.

FIG. 6 is a diagram showing an example of the filter characteristics of the low-pass filter 220. In the drawing, the horizontal axis indicates the frequency in units of [Hz]. In the drawing, the vertical axis on the left side indicates the impedance in units of [Ω]. In the drawing, the vertical axis on the right side indicates the phase difference in units of [°].

In the drawing, a waveform w3 indicates the impedance characteristics of the low-pass filter 220. Therefore, the value on the left side of the vertical axis is applied to the waveform w3. Further, a waveform w4 indicates the phase characteristics of the low-pass filter 220. Therefore, the value on the right side of the vertical axis is applied to the waveform w4.

As shown in the waveform w3, the low-pass filter 220 has an impedance characteristic that is lower in a low-frequency range than in a high-frequency range. In addition, the low-pass filter 220 has an impedance characteristic that is higher in the high-frequency range than in the low-frequency range.

More specifically, the impedance of the low-pass filter 220 may be equal to or less than 10 Ω in direct current. The reason for this is that, in a case where the impedance is more than 10Ω in direct current, an erroneous operation in which a light emitting element other than the intended light emitting element emits light is observed. In order to reliably prevent the erroneous operation, for example, the impedance of the low-pass filter 220 may preferably be equal to or less than 0.01Ω in direct current.

In addition, the impedance of the low-pass filter 220 may be equal to or more than 20 Ω at 3 MHz to 1 GHz. Here, since the impedance of the transmission line 210 is assumed to be about 45Ω, the impedance of the low-pass filter 220 may be equal to or more than ⅓ times and equal to or less than 3 times the impedance of the transmission line 210 at 3 MHz to 1 GHz.

In addition, in a case where the waveform w3 is viewed, it can be seen that the impedance converges to just under 50 Ω (about 46Ω) from 10 MHz to 1 GHz. As described above, the low-pass filter 220 may satisfy an impedance matching condition with the transmission line 210 that connects the reference potential terminal 134 and the low-pass filter 220, in the high-frequency range.

Thereafter, the operations and effects of the present exemplary embodiment will be described by showing two simulation results. A first simulation is a simulation assuming a case where a single-junction VCSEL is driven in a continuous wave (CW) for indirect time of flight (iToF). A second simulation is a simulation assuming a case where a triple-junction VCSEL is pulse-driven for direct time of flight (dToF).

FIG. 7 is a diagram showing an example of a circuit used in the first simulation according to a first comparative example. In the drawing, the identical or equivalent components and parts as or to FIG. 2 are denoted by the same reference numerals, and the description thereof will be omitted except for the following differences. In the first comparative example, a case where the transfer unit 130 is not provided is assumed. Therefore, in the first comparative example, the capacitance C2 due to the pn junction of the transfer unit 130 is also not formed.

L1 and L2 are parasitic inductances. More specifically, L1 corresponds to a parasitic inductance in a path from a power supply that supplies the light emitting potential VLD to the anode side of the VCSEL (more specifically, the anode of the light-emitting control thyristor 123). L2 corresponds to a parasitic inductance in a path from the cathode side of the VCSEL to the driver 140. In the simulation, the inductances of L1 and L2 are both set to 0.35 nH.

In addition, R1 is a parasitic resistance. In the simulation, the resistance value of R1 is set to 0.3Ω. In addition, the capacitance of C1 is estimated from a driving current loop inductance of 700 pF (approximate value in design) and a resonance period (to 1 ns), and is set to 35 pF.

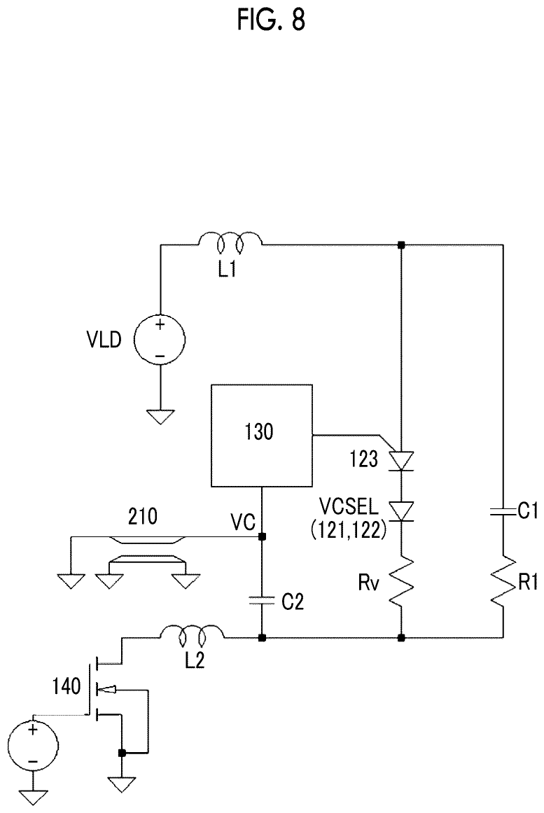

FIG. 8 is a diagram showing an example of a circuit used in the first simulation according to a second comparative example. In the drawing, the identical or equivalent components and parts as or to FIG. 7 are denoted by the same reference numerals, and the description thereof will be omitted except for the following differences. In the second comparative example, a case where the transfer unit 130 is provided and the reference potential terminal 134 is connected to the reference potential without passing through the low-pass filter 220 is assumed. Therefore, in the second comparative example, the capacitance C2 due to the pn junction of the transfer unit 130 is formed. In the simulation, the capacitance of C2 is set to 200 pF.

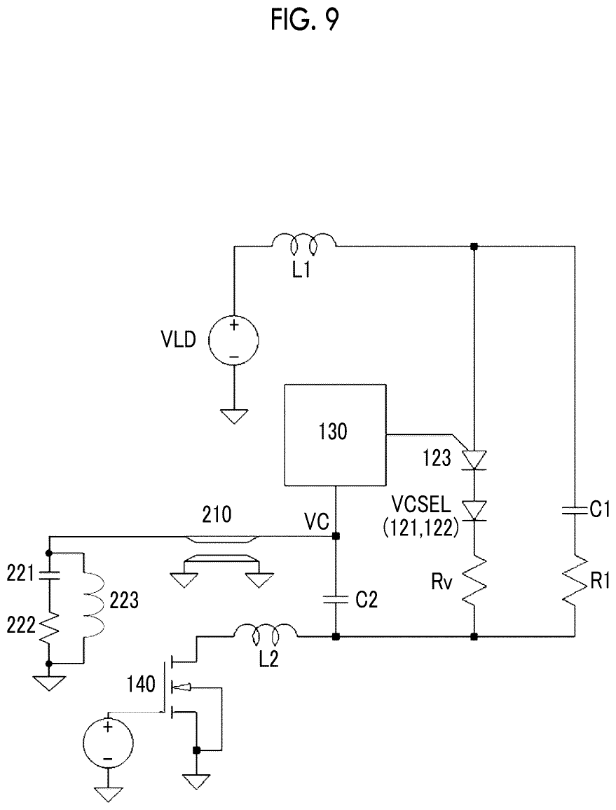

FIG. 9 is a diagram showing an example of a circuit used in the first simulation according to the present exemplary embodiment. In the drawing, the identical or equivalent components and parts as or to FIG. 8 are denoted by the same reference numerals, and the description thereof will be omitted except for the following differences. In the present exemplary embodiment, a case where the transfer unit 130 is provided and the reference potential terminal 134 is connected to the reference potential through the low-pass filter 220 is assumed. Therefore, in the present exemplary embodiment, the low-pass filter 220 is formed between the transmission line 210 and the reference potential, by a parallel circuit of the snubber circuit in which the capacitor 221 and the resistor 222 are connected in series, and the inductor 223.

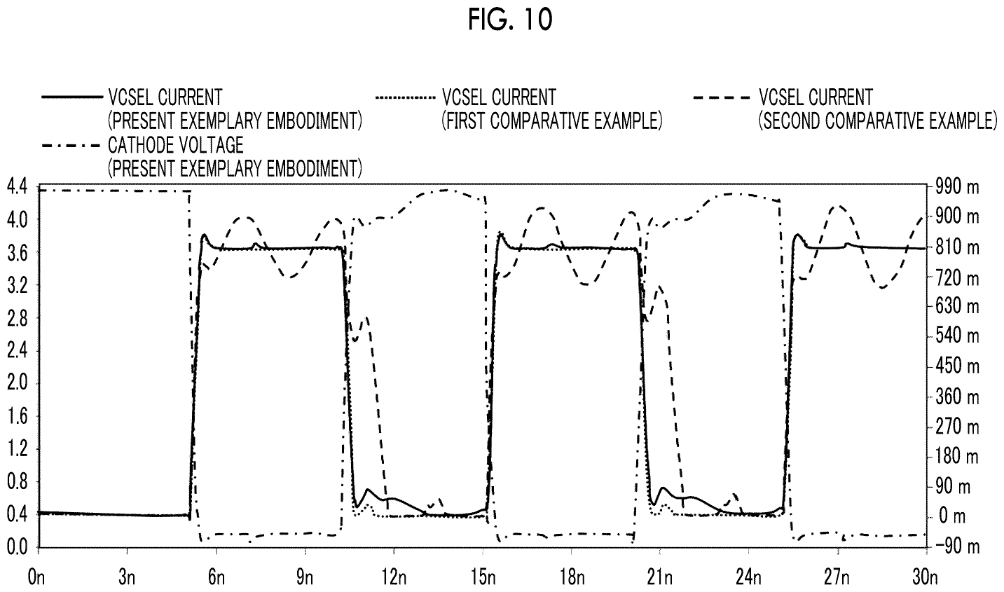

FIG. 10 is a diagram showing a result of the first simulation. In the drawing, the horizontal axis indicates represents time in units of [s]. In the drawing, the vertical axis on the left side indicates the voltage in units of [V]. In the drawing, the vertical axis on the right side indicates the current in units of [A].

In the drawing, the solid line indicates a VCSEL current waveform according to the present exemplary embodiment, the dotted line indicates a VCSEL current waveform according to the first comparative example, and the broken line indicates a VCSEL current waveform according to the second comparative example. Therefore, the value on the right side of the vertical axis is applied to the solid line, the dotted line, and the broken line. In the drawing, the one-dot chain line indicates a cathode voltage waveform according to the present exemplary embodiment. Therefore, the value on the left side of the vertical axis is applied to the one-dot chain line.

In the drawing, comparing the solid line and the broken line, the solid line shows a waveform closer to the dotted line than the broken line. This shows that a waveform closer to a waveform in a case where the transfer unit 130 is not provided is obtained by passing through the low-pass filter 220 as compared to a case without passing through the low-pass filter 220. That is, in the light emitting device 100 according to the present exemplary embodiment, it is possible to reduce waveform deterioration due to the capacitance of the transfer unit 130 without switching the connection state of the reference potential terminal 134, as compared with a case where the reference potential terminal 134 of the transfer unit 130 is directly connected to the reference potential.

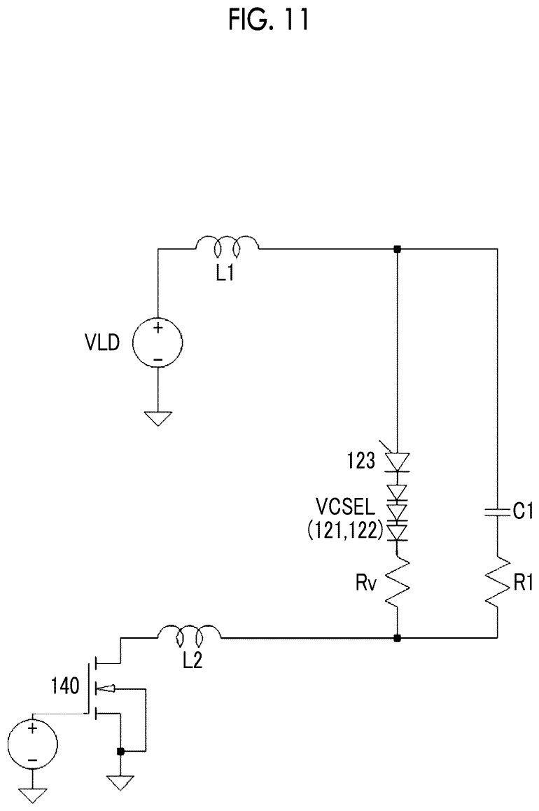

FIG. 11 is a diagram showing an example of a circuit used in the second simulation according to a third comparative example. In the drawing, the identical or equivalent components and parts as or to FIG. 7 are denoted by the same reference numerals, and the description thereof will be omitted except for the following differences. In the third comparative example, the VCSEL is changed from a single-junction to a triple-junction as compared with the first comparative example.

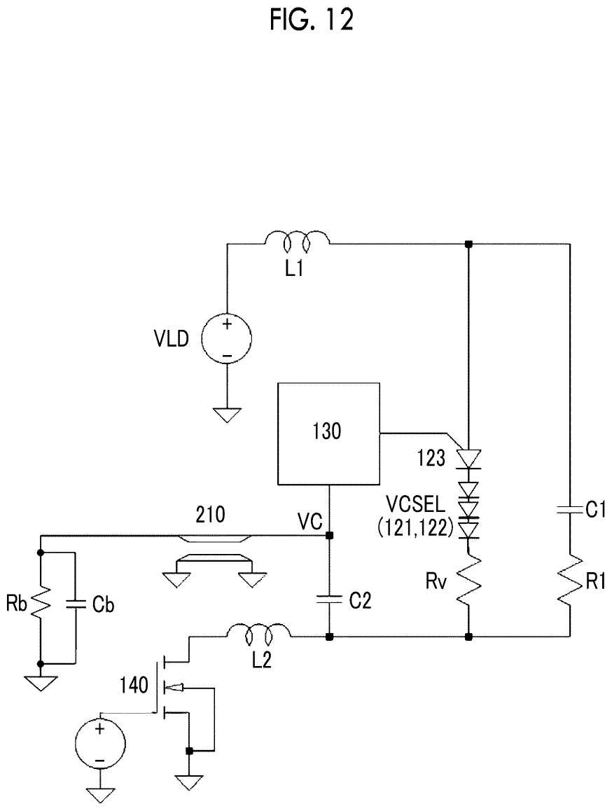

FIG. 12 is a diagram showing an example of a circuit used in the second simulation according to a fourth comparative example. In the drawing, the identical or equivalent components and parts as or to FIG. 11 are denoted by the same reference numerals, and the description thereof will be omitted except for the following differences. In the fourth comparative example, a case where the transfer unit 130 is provided and the reference potential terminal 134 is connected to the reference potential through a buffer is assumed.

In the drawing, Rb indicates an internal resistance of the buffer, and Cb indicates an output capacitance of the buffer. That is, the buffer is expressed by Rb and Cb. In the simulation, the resistance value of Rb is set to 5Ω. In addition, the capacitance of Cb is set to 15 pF.

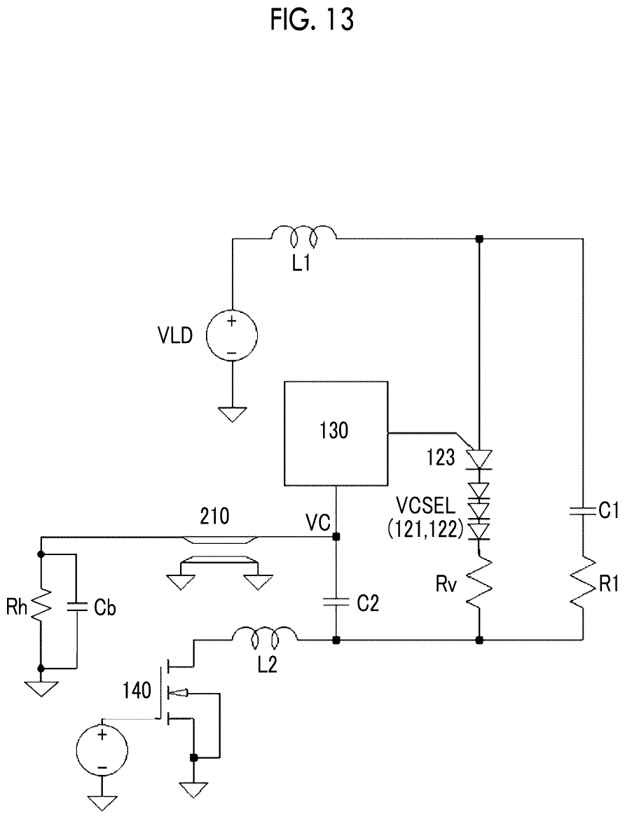

FIG. 13 is a diagram showing an example of a circuit used in the second simulation according to a fifth comparative example. In the drawing, the identical or equivalent components and parts as or to FIG. 12 are denoted by the same reference numerals, and the description thereof will be omitted except for the following differences. In the fifth comparative example, a case where the reference potential terminal 134 is terminated with a high impedance is assumed.

In the drawing, Rh indicates a termination resistance. In the simulation, the resistance value of Rh is set to 1 MΩ.

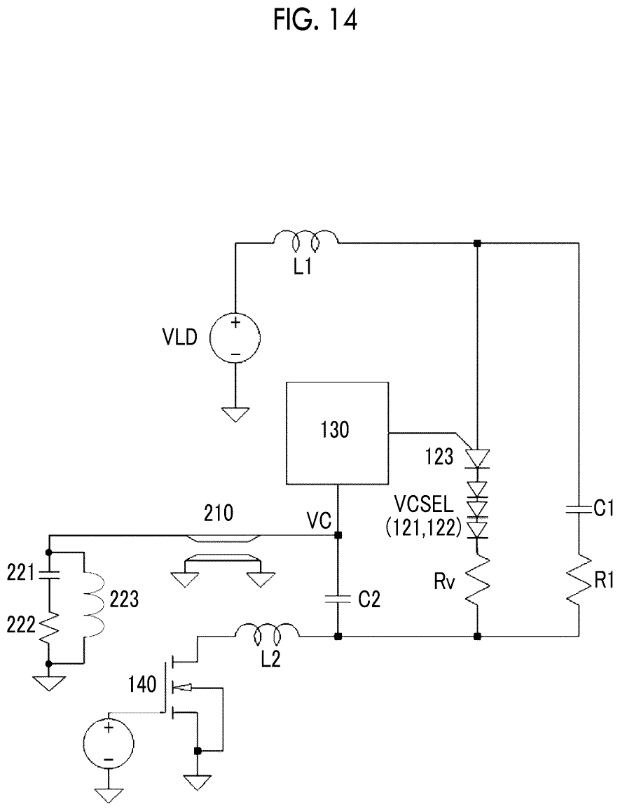

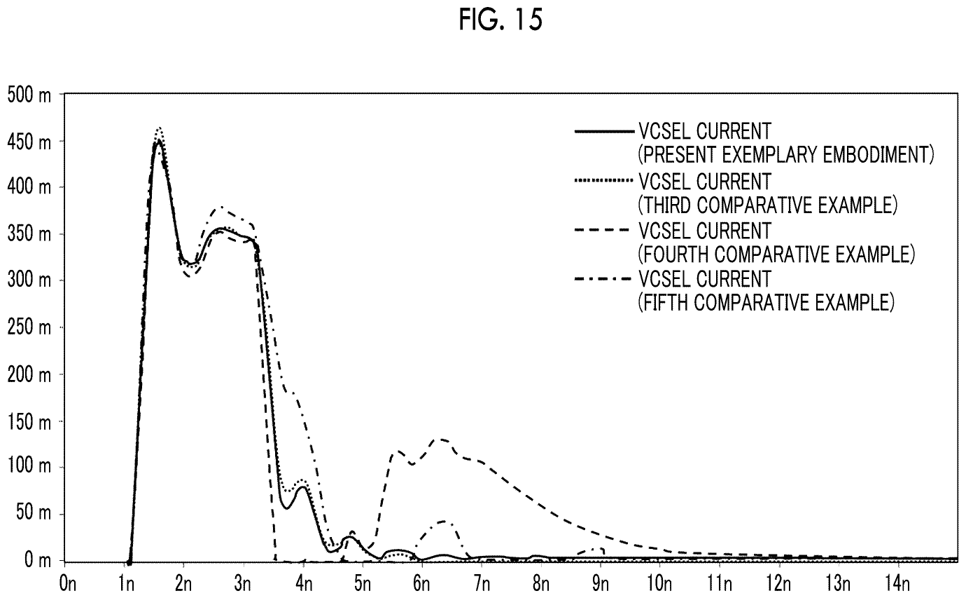

FIG. 14 is a diagram showing an example of a circuit used in the second simulation according to the present exemplary embodiment. In the drawing, the identical or equivalent components and parts as or to FIG. 9 are denoted by the same reference numerals, and the description thereof will be omitted except for the following differences. In the second simulation, the VCSEL is changed from a single-junction to a triple-junction as compared with the first simulation.

FIG. 15 is a diagram showing a result of the second simulation. In the drawing, the horizontal axis indicates represents time in units of [s]. In the drawing, the vertical axis indicates the current in units of [A].

In the drawing, the solid line indicates a VCSEL current waveform according to the present exemplary embodiment, the dotted line indicates a VCSEL current waveform according to the third comparative example, the broken line indicates a VCSEL current waveform according to the fourth comparative example, and the one-dot chain line indicates a VCSEL current waveform according to the fifth comparative example.

In the drawing, comparing the solid line, the broken line, and the one-dot chain line, the solid line shows a waveform closest to the dotted line. This shows that a waveform closer to a waveform in a case where the transfer unit 130 is not provided is obtained by connecting the reference potential terminal 134 to the reference potential through the low-pass filter 220, as compared with a case where the reference potential terminal 134 is connected to the reference potential through a buffer or is terminated with a high impedance.

More specifically, according to the broken line, in the fourth comparative example, it can be seen that the coupled oscillation with the Enh current loop causes the voltage to fall faster than a voltage in a case where the transfer unit 130 is not provided, but the response including the Enh terminal wiring appears largely later. In addition, according to the one-dot chain line, in the fifth comparative example, it can be seen that the deterioration of the falling edge is rather worse. On the other hand, according to the solid line, in the present exemplary embodiment, it can be seen that almost the same falling characteristics as in a case where the transfer unit 130 is not provided are obtained.

As described above, in the present exemplary embodiment, it is possible to stabilize the reference potential terminal 134 at the reference potential except for the time of light-emitting pulse driving, by the electrostatic capacitance between the reference potential terminal 134 and the cathode and the low-pass characteristics of the low-pass filter 220. Therefore, according to the present exemplary embodiment, it is possible to perform a stable transfer operation.

In addition, since the low-pass filter 220 has a high impedance at the time of light-emitting pulse driving, the voltage of the reference potential terminal 134 follows the change in the cathode voltage. Therefore, the reference potential terminal 134 is hardly affected by the capacitance between the reference potential terminal 134 and the cathode.

In this case, by snub-terminating the high-frequency components through the appropriate transmission line 210, it is possible to terminate the voltage change substantially in accordance with the reference potential without generating resonance due to the voltage change of the reference potential terminal 134 at the time of light-emitting pulse driving.

As described above, according to the present exemplary embodiment, it is possible to greatly reduce waveform deterioration due to the capacitance between the reference potential terminal 134 and the cathode, which is a problem in the addition of the transfer unit 130. In this case, according to the present exemplary embodiment, since switching of the GND connection state at the time of the transfer operation and the on state at the time of the light emitting operation is unnecessary, it is possible to simplify the circuit and the control of the circuit. Therefore, with the light emitting device 100 according to the present exemplary embodiment, it is possible to reduce waveform deterioration due to the capacitance of the transfer unit 130 without switching the connection state of the reference potential terminal 134, as compared with a case where the reference potential terminal 134 of the transfer unit 130 is directly connected to the reference potential.

The present disclosure is not limited to the above description, and can be variously modified and implemented in a range without departing from the gist of the present invention.

Regarding the above exemplary embodiments, the following supplementary notes will be further disclosed.

(((1)))

A light emitting device comprising:
a light emitting unit that includes a plurality of light emitting elements;
a transfer unit that transfers a signal for setting a light emitting element to turn into an on state among the plurality of light emitting elements; and
a low-pass filter provided between a reference potential terminal of the transfer unit and an external reference potential.
   (((2)))

The light emitting device according to (((1))), further comprising:
a transmission line provided between the reference potential terminal and the low-pass filter.
   (((3)))

The light emitting device according to (((2))),
wherein the low-pass filter includes a snubber circuit in which a capacitor and a resistor are connected in series.
   (((4)))

The light emitting device according to (((3))),
wherein the low-pass filter satisfies a predetermined impedance matching condition between the low-pass filter and the transmission line.
   (((5)))

The light emitting device according to (((3))) or (((4))),
wherein the low-pass filter further includes an inductor connected in parallel to the snubber circuit.
   (((6)))

The light emitting device according to any one of (((1))) to (((5))),
wherein the light emitting unit and the transfer unit are provided on a common semiconductor substrate.
   (((7)))

The light emitting device according to (((6))),
wherein the transfer unit includes a pn junction that is a structural body equivalent to the light emitting element.
   (((8)))

The light emitting device according to any one of (((1))) to (((7))),
wherein an impedance of the low-pass filter is equal to or less than 10 Ω in direct current.

The foregoing description of the exemplary embodiments of the present invention has been provided for the purposes of illustration and description. It is not intended to be exhaustive or to limit the invention to the precise forms disclosed. Obviously, many modifications and variations will be apparent to practitioners skilled in the art. The embodiments were chosen and described in order to best explain the principles of the invention and its practical applications, thereby enabling others skilled in the art to understand the invention for various embodiments and with the various modifications as are suited to the particular use contemplated. It is intended that the scope of the invention be defined by the following claims and their equivalents.

What is claimed is:

1. A light emitting device comprising:
a light emitting unit that includes a plurality of light emitting elements;
a transfer unit that transfers a signal for setting a light emitting element to turn into an on state among the plurality of light emitting elements; and
a low-pass filter provided between a reference potential terminal of the transfer unit and an external reference potential.

2. The light emitting device according to claim 1, further comprising:
a transmission line provided between the reference potential terminal and the low-pass filter.

3. The light emitting device according to claim 2,
wherein the low-pass filter includes a snubber circuit in which a capacitor and a resistor are connected in series.

4. The light emitting device according to claim 3,
wherein the low-pass filter satisfies a predetermined impedance matching condition between the low-pass filter and the transmission line.

5. The light emitting device according to claim 3,
wherein the low-pass filter further includes an inductor connected in parallel to the snubber circuit.

6. The light emitting device according to claim 1,
wherein the light emitting unit and the transfer unit are provided on a common semiconductor substrate.

7. The light emitting device according to claim 6,
wherein the transfer unit includes a pn junction that is a structural body equivalent to the light emitting element.

8. The light emitting device according to claim 1,
wherein an impedance of the low-pass filter is equal to or less than 10 Ω in direct current.

9. The light emitting device according to claim 2,
wherein an impedance of the low-pass filter is equal to or less than 10 Ω in direct current.

10. The light emitting device according to claim 3,
wherein an impedance of the low-pass filter is equal to or less than 10Ω in direct current.

11. The light emitting device according to claim 4,
wherein an impedance of the low-pass filter is equal to or less than 10 Ω in direct current.

12. The light emitting device according to claim 5,
wherein an impedance of the low-pass filter is equal to or less than 10 Ω in direct current.

13. The light emitting device according to claim 6,
wherein an impedance of the low-pass filter is equal to or less than 10 Ω in direct current.

14. The light emitting device according to claim 7,
wherein an impedance of the low-pass filter is equal to or less than 10 Ω in direct current.
